(19) United States
(12) Patent Application Publication
(10) Pub. No.: US 2012/0269365 A1
(43) Pub. Date: Oct. 25, 2012

(54) ACOUSTIC APPARATUS, ACOUSTIC SYSTEM, AND AUDIO SIGNAL CONTROL METHOD

(75) Inventors: Yuichi Ochiai, Toyota-shi (JP); Seigen Maeno, Okazaki-shi (JP)

(73) Assignee: TOYOTA JIDOSHA KABUSHIKI KAISHA, Toyota-shi, Aichi-ken (JP)

(21) Appl. No.: 13/518,223

(22) PCT Filed: Dec. 14, 2010
(86) PCT No.: PCT/IB2010/003264

§ 371 Date: Jun. 21, 2012

(30) Foreign Application Priority Data
Dec. 22, 2009 (JP) 2009-290839

(51) Int. Cl. H03F 99/00

(52) U.S. Cl. 381/120

(57) ABSTRACT

An acoustic apparatus includes: a first amplification unit; and an audio signal control unit that controls an audio signal input to the first amplification unit, wherein if a second amplification unit is connected to an output of the first amplification unit, a level control of the audio signal by the audio signal control unit is terminated.

### BACKGROUND OF THE INVENTION

1. Field of the Invention

The invention relates to an acoustic apparatus and an acoustic system in which another amplification unit is connected to an amplification unit for amplifying an audio signal. The invention also relates to a method of controlling an audio signal in a case where another amplification unit is connected to an amplification unit for amplifying an audio signal.

2. Description of the Related Art

Japanese Patent Application Publication No. 2004-120413 (JP-A-2004-120413), for example, describes an acoustic apparatus that stops an operation of a built-in amplifier provided in an apparatus main body when an external .amplifier is connected to the apparatus main body. In the described acoustic apparatus, when operation of the built-in amplifier is stopped, an audio signal generated by a sound source is amplified by the external amplifier rather than the built-in amplifier, whereupon the reproduced sound is generated by a speaker that is connected to the external amplifier.

FIG. 1 is a block diagram showing the configuration of an acoustic system 100 in which an amplifier unit 12 having a built-in amplifier 8 is connected to an audio unit 11 having a built-in amplifier 4. In the acoustic system 100, when the volume of an audio signal transmitted to the amplifier unit 12 is adjusted by a volume adjustment unit 3 of the audio unit 11, and therefore an anti-noise characteristic and an S/N (Signal to Noise ratio) are likely to deteriorate on an audio transmission path.

For example, the amplifier 4 has noise, and therefore, when the volume is reduced by the volume adjustment unit 3 disposed in front of the amplifier 4, a level of the audio signal input to the amplifier 4 decreases. Thus, a reduction in the S value occurs, leading to S/N deterioration. Further, external noise introduced onto a transmission path 6 is amplified by the amplifier 8 of the amplifier unit 12, and therefore, when the signal level of the audio signal output from the audio unit 11 decreases, the effect of the external noise increases, leading to deterioration of the anti-noise characteristic.

### SUMMARY OF THE INVENTION

The invention provides an acoustic apparatus, an acoustic system, and an audio signal control method for suppressing the effects of noise.

A first aspect of the invention relates to an acoustic apparatus. The acoustic apparatus includes: a first amplification unit; and an audiosignal control unit that controls an audio signal input to the first amplification unit, wherein if a second amplification unit is connected to an output of the first amplification unit, a level control of the audio signal by the audio signal control unit is terminated.

A second aspect of the invention relates to an acoustic system. The acoustic system includes: a first acoustic unit that includes a first amplification unit and an audio signal control unit that controls an audio signal input to the first amplification unit; and a second acoustic unit that includes a second amplification unit connected to an output of the first amplification unit, wherein control of the audio signal by the audio signal control unit is terminated.

A third aspect of the invention relates to an audio signal control method.

The audio signal control method includes: determining whether a second amplification unit is connected to an output of a first amplification unit; and terminating a level control of an audio signal that is input to the first amplification unit if it is determined that the second amplification unit is connected to the output of the first amplification unit.

According to the invention, the effects of noise can be suppressed.

### BRIEF DESCRIPTION OF THE DRAWINGS

The features, advantages, and technical and industrial significance of the invention will be described in the following detailed description of example embodiments of the invention with reference to the accompanying drawings, in which like numerals denote like elements, and wherein:

FIG. 1 is a block diagram showing the configuration of an acoustic system according to a related technical field;

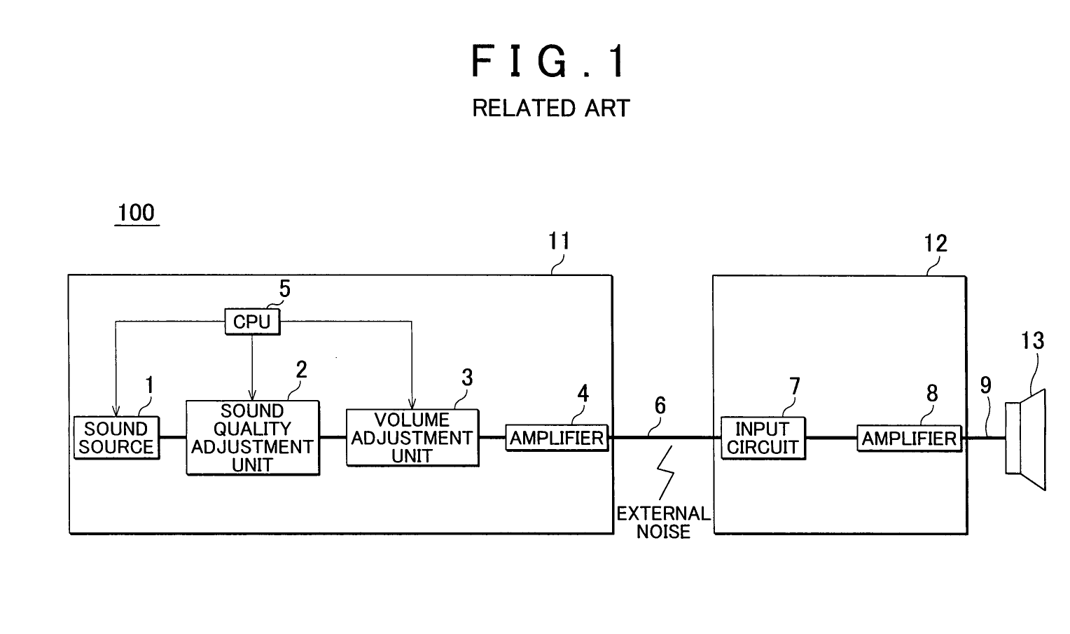

FIG. 2 is a block diagram showing the configuration of an acoustic system according to a first embodiment of the invention;

FIG. 3 is a block diagram showing the configuration of an acoustic system according to a second embodiment of the invention;

FIG. 4 is a block diagram showing the configuration of an acoustic system in which an amplifier unit is not provided in the transmission path between an amplifier built into an audio unit and a speaker;

FIG. 5 is a block diagram showing the configuration of an acoustic system in which an amplifier unit is provided in the transmission path between an amplifier built into an audio unit and a speaker;

FIG. 6 is a block diagram showing the configuration of an acoustic system in which an amplifier unit is provided in the transmission path between an audio unit without a built-in amplifier and a speaker; and

FIG. 7 is a flowchart showing an audio signal control method according to the invention.

### DETAILED DESCRIPTION OF EMBODIMENTS

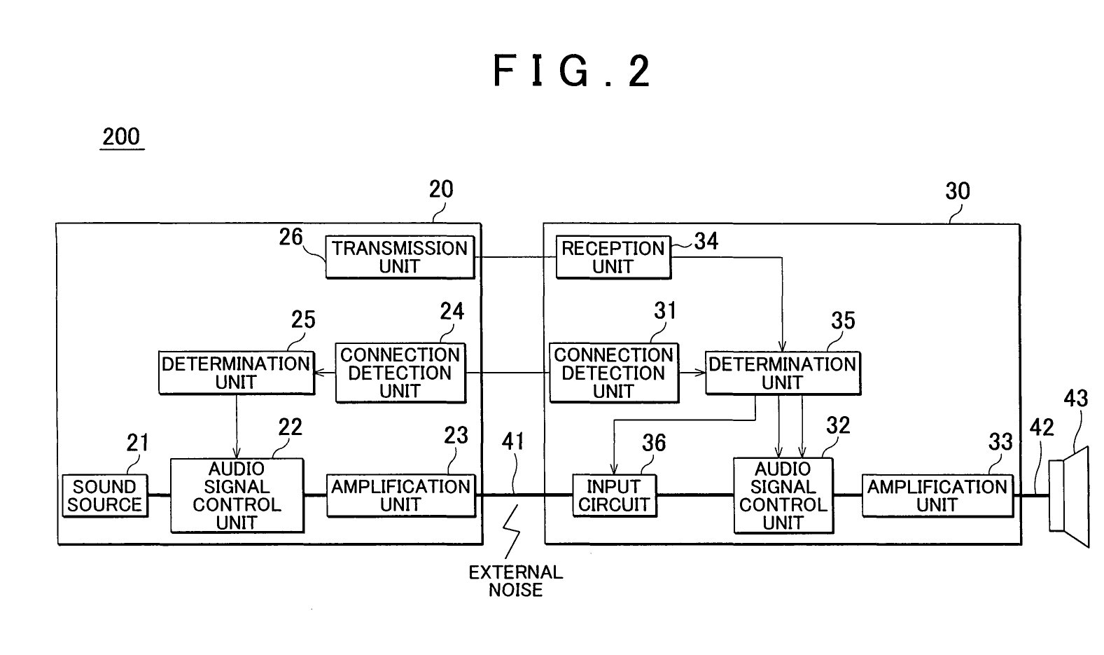

First and second embodiments of the invention are described below with reference to the drawings. FIG. 2 is a block diagram showing the configuration of an acoustic system 200, installed in a vehicle, according to the first embodiment of the invention. The acoustic system 200 includes an audio unit 20, an amplifier unit 30, and a speaker 43. The audio unit 20 includes a first amplification unit 23, and a first audio signal control unit 22 that controls the audio signal (to be referred to hereafter as an “audio signal A”) input into the first amplification unit 23. The amplifier unit 30 is an external unit (a second amplification unit) provided between the audio unit 20 and the speaker 43.

In the acoustic system 200, as shown in FIG. 2, when the amplifier unit 30 is connected to an output of the first amplification unit 23 via a transmission path 41, control of a level (in other words, a volume) of the audio signal A by the first audio signal control unit 22 is stopped, and therefore the level of the audio .signal A input to the first amplification unit 23 from a sound source 21 does not decrease. As a result, even if external noise is input into the transmission path 41, S/N deterioration and deterioration of an anti-noise characteristic are suppressed.

More specifically, if an audio signal that is output from the sound source 21 is input to the first amplification unit 23 at a high voltage level, i.e. without being subjected to signal level reduction by the first audio signal control unit 22, the level of the output signal output by the first amplification unit 23 does not decrease either, and therefore S/N deterioration at an output of the audio unit 20 can be suppressed to a minimum. Furthermore, the signal level of the audio signal output by the audio unit 20 does not decrease, and therefore, even if external noise introduced onto the transmission path 41 is amplified by the amplifier unit 30 side, effects of the external noise may be suppressed as long as the external noise is amplified following appropriate volume reduction on the amplifier unit 30 side.

Next, the configuration shown in FIG. 2 will be described in further detail.

The audio unit 20 further includes, the sound source 21, a connection detection unit 24, a determination unit 25, and a transmission unit 26, for example.

The sound source 21 serves as an audio signal output source (generation source). The sound source 21 outputs an audio signal obtained upon reception of an audio signal or a broadcast (AM, FM, TV, and so on), which is obtained by reproducing a recording medium (a CD or the like, for example).

The connection detection unit 24 detects a connection condition of the output of the first amplification unit 23, and determines Whether the amplifier unit 30 (more specifically, a second amplification unit 33 provided in the amplifier unit 30) is connected to the output of the first amplification unit 23. By receiving information (ID information relating to the amplifier unit 30, for example) from which it can be determined, either directly or indirectly, that the amplifier unit 30 is connected, the connection detection unit 24 determines that the amplifier unit 30 is connected to the output of the first amplification unit 23. If the information is not received, the connection detection unit 24 determines that the amplifier unit 30 is not connected to the output of the first amplification unit 23.

The determination unit 25 determines whether the level, control of the audio signal A executed by the first control unit 22 should be terminated in accordance with the connection condition of the output of the first amplification unit 23. If the connection detection unit 24 determines that the amplifier unit 30 is not connected to the output of the first amplification unit 23, the determination unit 25 determines that level control of the audio signal A is not to be terminated, and if the connection detection unit 24 determines that the amplifier unit 30 is connected to the output of the first amplification unit 23, the determination unit 25 determines that level control of the audio signal A is to be terminated.

For example, if the connection detection unit 24 determines that the amplifier unit 30 is connected to the output of the first amplification unit 23, the control to reduce the level of the audio signal A below a predetermined value is terminated. Hence, even if an adjustment is performed externally to reduce the volume, the level of the audio signal A maintained above the prescribed value, and as a result, S/N and anti-noise characteristic deterioration can be suppressed to a minimum. The prescribed value may be set to an output level of the sound source 21, for example. By setting the prescribed value to the output level of the sound source 21, the level of the audio signal A is prevented from falling below the output level of the sound source 21 even if the volume is adjusted, and therefore S/N and anti-noise characteristic deterioration can be suppressed.

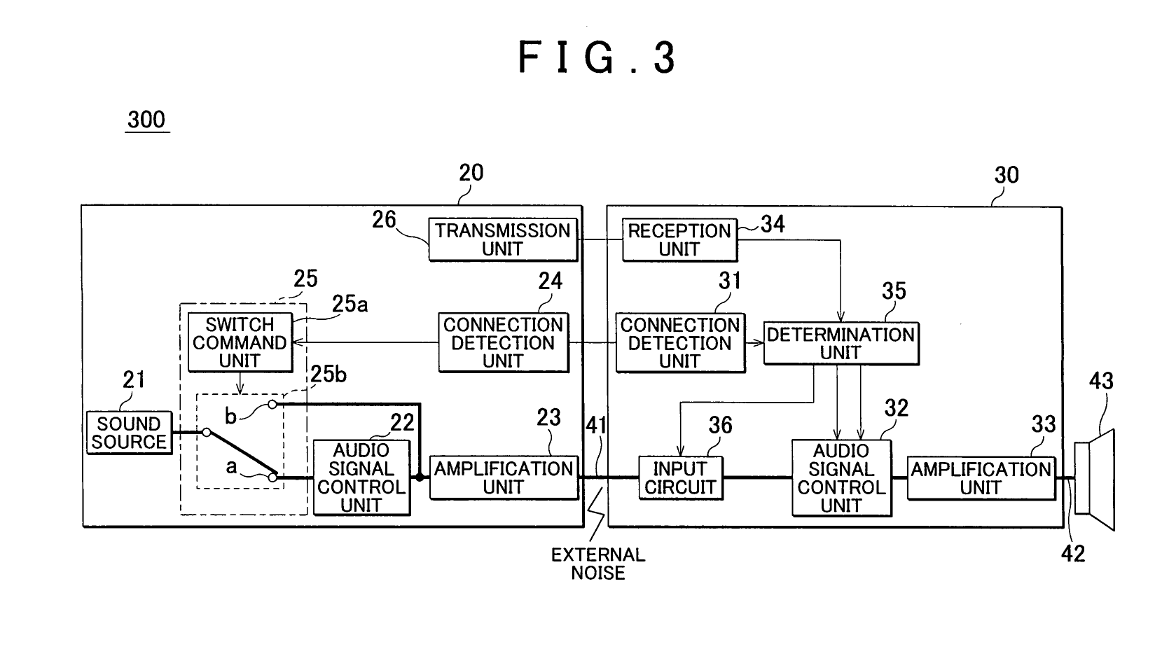

The determination unit 25 may also be constituted as shown in FIG. 3. FIG. 3 is a block diagram showing the configuration of an acoustic system 300 that is installed on a vehicle according to the second embodiment of the invention. The determination unit 25 includes a switch command unit 25a and a switching unit 25b that switches an output of the sound source 21 in accordance with a switch command from the switch command unit 25a. The switch command unit 25a subjects the switch 25b to switch control for switching the output of the sound source 21 in accordance with the connection condition of the output of the first amplification unit 23.

For example, if the connection detection unit 24 determines that the amplifier unit 30 is connected to the output of the first amplification unit 23, the switching unit 25b switches the output of the sound source 21 from contact a to contact b so that the audio signal A bypasses the first audio signal control unit 22. As a result, level control of the audio signal A by the first audio signal control unit 22 is terminated.

Note that the determination unit 25, as well as the switch command unit 25a and switching unit 25b, may be implemented by hardware, such as a microcomputer, or by software run on the hardware.

Further, if the connection detection unit 24 determines that the amplifier unit 30 is connected to the output of the first amplification unit 23, the transmission unit 26, shown in FIGS. 2 and 3, transmits control content to be performed on the audio signal A by the first audio signal control unit 22 to the amplifier unit 30. Thus, the amplifier unit 30 can recognize the control content to be performed on the audio signal A by the 20 first audio signal control unit 22. The audio signal input into the amplifier unit 30 may then be controlled in accordance with the control content on the amplifier unit 30 side rather than the audio unit 20 side. In other words, the amplifier unit 30 may control an amplified signal, which is the audio signal A amplified by the first amplification unit 23, in accordance with the control content.

As the control content to be performed on the audio signal A by the first audio signal control unit 22, the transmission unit 26 transmits stoppage content relating to level control of the audio signal A, for example. Hence, even when level control of the audio signal A is stopped on the audio unit 20 side, audio signal level control can be implemented on the amplifier unit 30 side by applying identical or corresponding content to the stoppage content such that an audio is output from the speaker 43.

The amplifier unit 30 includes an input circuit 36, a reception unit 34, a second audio signal control unit 32, the second amplification unit 33, a second connection detection unit 31, and a second determination unit 35.

The input circuit 36 receives an audio signal from the audio unit 20 via the transmission path 41.

The reception unit 34 receives the control content to be performed on the audio signal A by the first audio signal control unit 22 from the transmission unit 26 of the audio unit 20.

The second audio signal control unit 32 controls the audio signal (to be referred to hereafter as a “audio signal B”) that is input to the second amplification unit 33 in accordance with the control content to be performed on the audio signal A by the first audio signal control unit 22, the control content being received by the reception unit 34.

The second connection detection unit 31 determines whether the audio unit 20 is connected. If the connection detection unit 31 receives information (ID information relating to the audio unit 20, for example) from which it can be determined, either directly or indirectly, that the audio unit 20 is connected, the connection detection unit 31 can determine that the audio unit 20 is connected to the amplifier unit 30. If the information is not received, the connection detection unit 31 determines that the audio unit 20 is not connected to the amplifier unit 30.

The second determination unit 35 modifies the method of controlling the audio signal that is input to the amplifier unit 30 in accordance with the connection condition of the audio unit 20 (in other words, in accordance with whether the amplifier unit 30 is connected to the output of the first amplification unit 23). Hence, even if the level of the audio signal that is input to the amplifier unit 30 varies in accordance with whether level control of the audio signal A is stopped, it is possible to respond to this variation. For example, the method of controlling the audio signal input into the. amplifier unit 30 may be modified by modifying the input threshold of the input circuit 36.

Note that the second determination unit 35 may be implemented by hardware such as a microcomputer or through software run on the hardware.

Next, specific examples of the respective configurations of the acoustic systems 200, 300 shown in FIGS. 2 and 3 will be described.

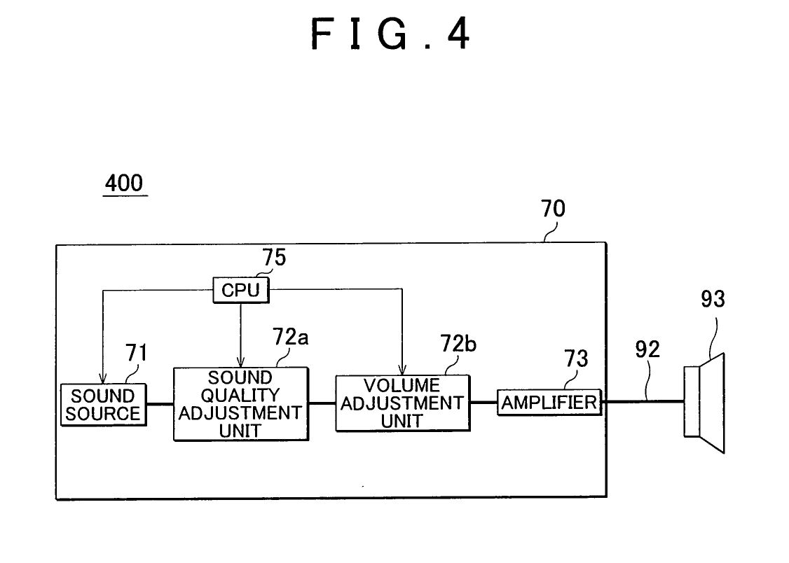

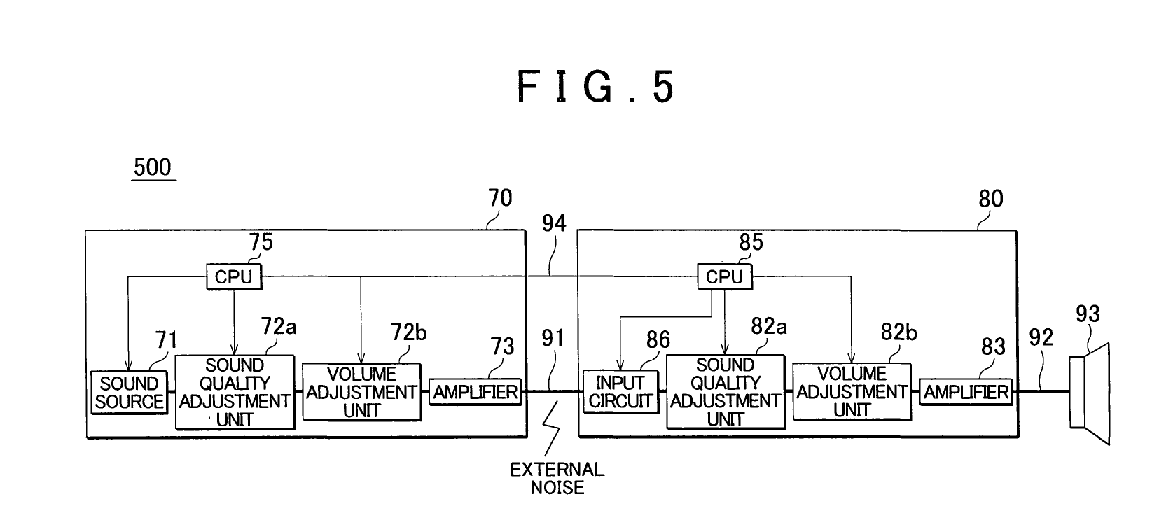

FIG. 4 is a block diagram showing the configuration of an acoustic system 400 in which an amplifier unit is not provided on the transmission path 92 between the amplifier 73, which is built into an audio unit 70, and a speaker 93. FIG. 5 is a block diagram showing the configuration of an acoustic system 500 in which an amplifier unit 80 is provided on the transmission path 92 between the amplifier 73 and the speaker 93. FIG. 5 shows a configuration in which the amplifier unit 80 is provided externally as an add-on option to the configuration shown in FIG. 4.

The audio unit 70 includes a sound source 71; a sound quality adjustment unit 72a, such as an equalizer; a volume adjustment unit 72b; an amplifier 73; and a central processing unit (CPU) 75. When compared with the configurations shown in FIGS. 2 and 3, the sound source 71 corresponds to the sound source 21. The sound quality adjustment unit 72a and volume adjustment unit 72b correspond to the first audio signal control unit 22 that processes the audio signal A. The amplifier 73 corresponds to the first amplification unit 23. The CPU 75 corresponds to the connection detection unit 24, determination unit 25, and transmission unit 26.

The amplifier unit 80 includes an input circuit 86, a sound quality adjustment unit 82a such as an equalizer, a volume adjustment unit 82b, an amplifier 83, and a CPU 85. When compared with the configurations shown in FIGS. 2 and 3, the input circuit 86 corresponds to the input circuit 36. The sound quality adjustment unit 82a and volume adjustment unit 82b correspond to the second audio signal control unit 32 for performing processing control on the audio signal B. The amplifier 83 corresponds to the second amplification unit 33. The CPU 85 corresponds to the connection detection unit 31, determination unit 35, and reception unit 34.

The CPU 75 of the audio unit 70 determines the connection condition of the amplifier unit 80 through communication via a communication line 94 with the CPU 85. The connection condition of the amplifier unit 80 is determined in accordance With whether ID information relating to the amplifier unit 80 is received through the communication line 94, for example. The connection condition of the amplifier unit 80 may also be determined in accordance with a voltage input that varies depending on whether the amplifier unit 80 is connected.

If the CPU 75 of the audio unit 70 determines that the amplifier unit 80 is connected through communication via the communication line 94, the CPU 75 terminates audio signal control functions of the sound quality adjustment unit 82a and the volume adjustment unit 82b (i.e. halts control of the audio signal A). For example, control of the audio signal A is stopped by fixing the volume adjusted by the volume adjustment unit 82 to a predetermined value.

Further, if the CPU 75 of the audio unit 70 determines that the amplifier unit 80 is connected through communication via the communication line 94, because the audio signal, control functions of the sound quality adjustment unit 72a and the volume adjustment unit 72b are stopped, the CPU 75 transmits requested setting values from a user relating to the sound quality, volume, and so on to the amplifier unit 80 via the communication line 94. The CPU 85 of the amplifier unit 80 then adjusts the audio signal B in accordance with the requested setting values from the audio unit 70 using the sound quality adjustment unit 82a and the volume adjustment unit 82b. An audio signal adjusted by the sound quality adjustment unit 82a and volume adjustment unit 82b is then amplified by the amplifier 83 and output to the speaker 93.

Hence, the audio signal from the sound source 71 is input into the amplifier 73 without being adjusted by the sound quality adjustment unit 72a and the volume adjustment unit 72b, and therefore the level of the output signal from the amplifier 73 does not decrease. As a result, S/N deterioration at the output of the audio unit 70 is minimized. Furthermore, sound quality adjustment, volume adjustment, and audio signal amplification are performed on the amplifier unit 80 side, but because a noise performance of the sound quality adjustment unit 82a, volume adjustment unit 82b, and amplifier 83 is typically better than the noise performance on the audio unit 70 side, S/N deterioration can be suppressed over the entire acoustic system. Moreover, even if external noise input into the transmission path 41 is amplified on the amplifier unit 80 side, the volume is amplified by the amplifier 83 following appropriate volume reduction by the volume adjustment unit 82b on the amplifier unit 80 side, and therefore the effects of the external noise can be suppressed.

Further, if the amplifier unit 80 is not connected, the CPU 75 of the audio unit 70 controls the audio signal using the audio signal adjustment functions of the sound quality adjustment unit 72a and volume adjustment unit 72b, and if the amplifier unit 80 is connected, the CPU 75 of the audio unit 70 communicates with the CPU 85 of the amplifier unit 80 and instructs the CPU 85 to control the audio signal using the audio signal adjustment functions of the sound quality adjustment unit 82a and volume adjustment unit 82b, instead of the sound quality adjustment unit 72a and volume adjustment unit 72b. Accordingly, the model of the audio unit in an acoustic system, in which the amplifier unit 80 is provided as an option, and the model of the audio unit in an acoustic system, in which the amplifier unit 80 is not provided as an optional extra, may be standardized while greatly suppressing the effects of noise.

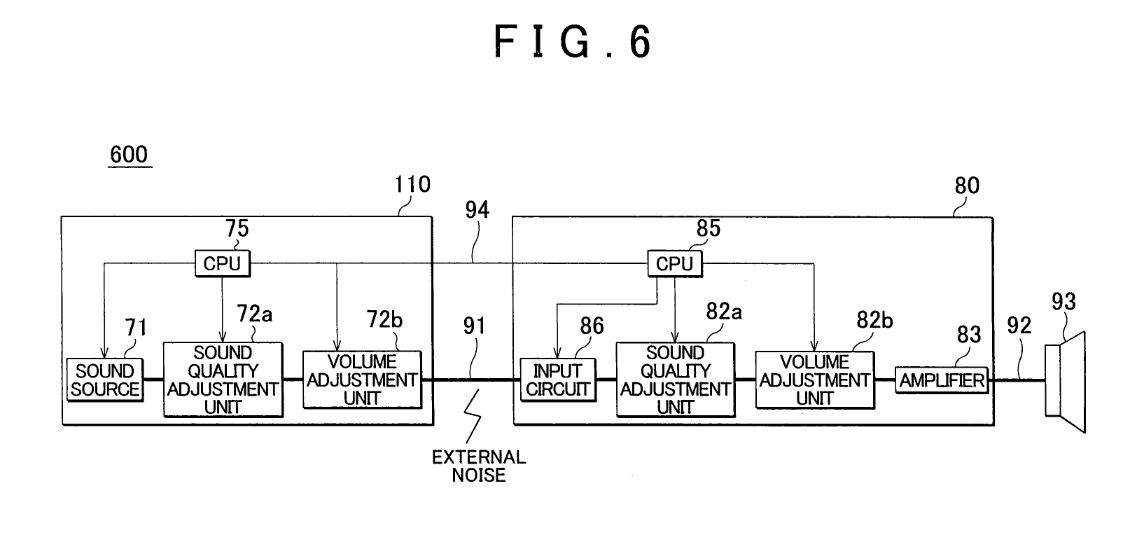

FIG. 6 is a block diagram showing the configuration of an acoustic system 600 in which the amplifier unit 80 is provided on the transmission path 92 between an audio unit 110, which does not include a built-in amplifier, and the speaker 93. The CPU 85 of the amplifier unit 80 may determine whether the audio unit includes a built-in amplifier (FIG. 5) or does not include a built-in amplifier (FIG. 6) by communicating the CPU 85 via the communication line 94 with the CPU 75. The CPU 85 of the amplifier unit 80 switches a setting value of the input circuit 86 and adjustment values of the sound quality adjustment unit 82a and volume adjustment unit 82b to appropriate values for the model of the connected audio unit. Thus, the model of the amplifier unit may be standardized regardless of whether the audio unit includes a built-in amplifier.

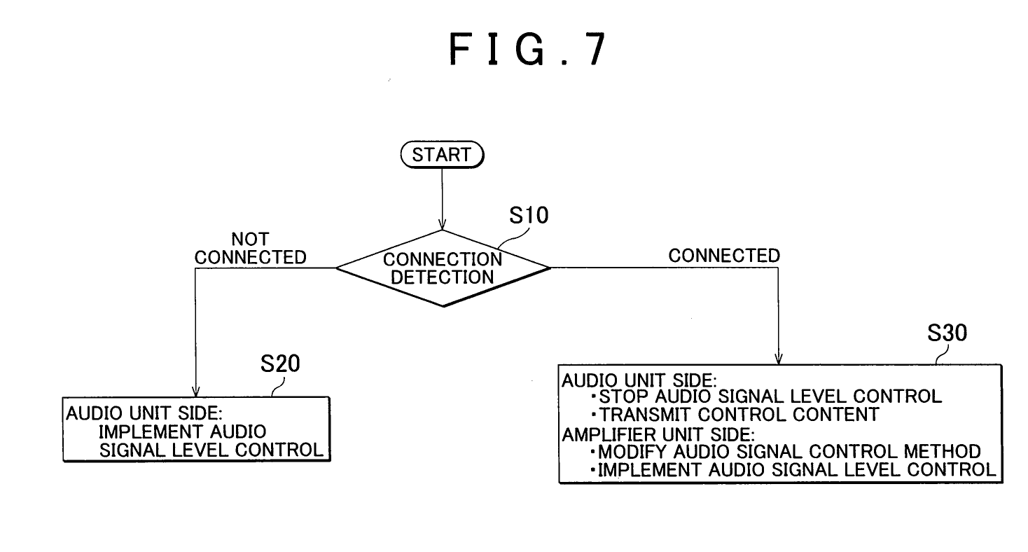

FIG. 7 is a flowchart showing an example of an audio signal control method according to the invention. The audio unit 70 periodically executes a detection operation to determine the connection condition of the amplifier unit 80 (step S10). If the audio unit 70 determines that the amplifier unit 80 is not connected, the audio unit 70 controls the voltage level of the audio signal A using the audio signal adjustment functions of the volume adjustment unit 72b and so on in accordance with a requested value from the user (step S20).

If the audio unit 70 determines that the amplifier unit 80 is connected, however, the audio unit 70 stops controlling the audio signal A (controlling the voltage level of the audio signal A and so on) using the audio signal adjustment functions of the volume adjustment unit 72b and so on, and transmits the control content to be performed on the audio signal A using the audio signal adjustment functions to the amplifier unit 80 together with ID information from which the model of the audio unit 70 can be specified (step S30). Once the ID information and the control content to be performed on the audio signal A using the audio signal adjustment functions from the audio unit 70 are 15 received, the amplifier unit 80 modifies the method of controlling the audio signal from the audio unit 70 (for example, selects an equalizer appropriate for the model of the audio unit 70) in accordance with the control content and ID information, and controls the audio signal B (controls the voltage level of the audio signal B and so on) using the audio signal adjustment functions of the volume adjustment unit 82b and so on in accordance with the control content (step S30).

The first and second embodiments of the invention were described in detail above, but the invention is not limited to the described embodiments. Various modifications and substitutions may be applied to the above embodiments without departing from the scope of the invention.

For example, the above embodiments relate to an acoustic system installed in a vehicle, but the invention may be used somewhere other than in a vehicle (at home, for example).

1. An acoustic apparatus comprising:
a first amplification unit; and
an audio signal control unit that controls an audio signal input to the first amplification unit, wherein
if a second amplification unit is connected to an output of the first amplification unit, a level control of the audio signal by the audio signal control unit is terminated.

2. The acoustic apparatus according to claim 1, wherein, if the second amplification unit is connected to the output of the first amplification unit, execution of a control to reduce the level of the audio signal below a predetermined level by the audio signal control unit is terminated.

3. The acoustic apparatus according to claim 2, wherein, if the second amplification unit is connected to the output of the first amplification unit, execution of a control to reduce the level of the audio signal below an output level of an output source of the audio signal by the audio signal control unit is terminated.

4. The acoustic apparatus according to any one of claims 1 to 3, further comprising a transmission unit that transmits control content to be performed on the audio signal by the audio signal control unit to the second amplification unit if the second amplification unit is connected to the output of the first amplification unit.

5. An acoustic system comprising:
a first acoustic unit that includes a first amplification unit and an audio signal control unit that controls an audio signal input to the first amplification unit; and
a second acoustic unit that includes a second amplification unit connected to an output of the first amplification unit, wherein
control of the audio signal by the audio signal control unit is terminated.

6. The acoustic system according to claim 5, wherein the second acoustic unit includes a second control unit that controls an audio signal input into the second amplification unit in accordance with control content to be performed on the audio signal by the audio signal control unit.

7. An audio signal control method comprising:
determining whether a second amplification unit is connected to an output of a first amplification unit; and
terminating a level control of an audio signal that is input to the first amplification unit if it is determined that the second amplification unit is connected to the output of the first amplification unit.

8. The audio signal control method according to claim 7, further comprising:
modifying a method of controlling an audio signal that is input to the second amplification unit in accordance with whether the second amplification unit is connected to the output of the first amplification unit.

9. The audio signal control method according to claim 7 or 8, further comprising:
transmitting control content to be performed on the audio signal that is input to the first amplification unit to the second amplification unit if the second amplification unit is connected to the output of the first amplification unit.

10 The audio signal control method according to any one of claims 7 to 9, further comprising:
controlling an audio signal that is input to the second amplification unit in accordance with control content to be performed on the audio signal that is input to the first amplification unit if the second amplification unit is connected to the output of the first amplification unit.
